(19) United States
(12) Patent Application Publication
(10) Pub. No.: US 2025/0294736 A1
(43) Pub. Date: Sep. 18, 2025

(54) ULTRAFAST TWO-DIMENSIONAL (2D) FLASH MEMORY DEVICE BASED ON FOWLER-NORDHEIM (FN) TUNNELING AND PREPARATION METHOD THEREOF

(71) Applicant: Fudan University, Shanghai (CN)

(72) Inventors: Chunsen LIU, Shanghai (CN); Yuxin KONG, Shanghai (CN); Peng ZHOU, Shanghai (CN)

(21) Appl. No.: 19/222,927

(22) Filed: May 29, 2025

(30) Foreign Application Priority Data
Mar. 11, 2025 (CN) 202510281072.6

(51) Int. Cl. H10B 41/30; H10D 30/01; H10D 30/47

(52) U.S. Cl. CPC H10B 41/30; H10D 30/017; H10D 30/481

(57) ABSTRACT

An ultrafast two-dimensional (2D) flash memory device based on Fowler-Nordheim (FN) tunneling, including a substrate, a gate electrode, a blocking layer, a floating gate, a tunneling layer, a 2D channel, a source electrode and a drain electrode. The gate electrode is provided at a middle of the substrate. The blocking layer is configured to cover the gate electrode and the substrate. The floating gate is provided on the blocking layer, and is entirely encompassed within a coverage area of the gate electrode. The tunneling layer is configured to cover the floating gate and the blocking layer. The 2D channel is provided on the tunneling layer, and is entirely encompassed within a coverage area of the floating gate. The source electrode and the drain electrode are configured to partially overlap with the 2D channel. A method for preparing such device is also provided.

### CROSS-REFERENCE TO RELATED APPLICATIONS

This application claims the benefit of priority from Chinese Patent Application No. 202510281072.6, filed on Mar. 11, 2025. The content of the aforementioned application, including any intervening amendments made thereto, is incorporated herein by reference in its entirety.

### TECHNICAL FIELD

This application relates to semiconductor memories, and more particularly to an ultrafast two-dimensional (2D) flash memory device based on Fowler-Nordheim (FN) tunneling and a preparation method thereof.

### BACKGROUND

With the rapid advancement of artificial intelligence and big data technologies, the traditional charge storage memory devices become increasingly limited, gradually emerging as a bottleneck for in the development of information technology. Dynamic random-access memory (DRAM) achieves nanosecond-order high-speed reading and writing operations through a capacitor-based charge storage mechanism. However, due to its volatility, frequent refresh operations are required, resulting in significantly increased power consumption and thus making it unsuitable for the low-power applications. Flash memory enables non-volatile data storage through charge trapping, but is limited by its low program/erase speed (millisecond-order) and poor endurance, making it difficult to meet the requirements of computing-in-memory architectures for the high-speed on-chip memory.

Two-dimensional (2D) semiconductor materials have a layered structure composed of single or several atomic layers, such as transition metal dichalcogenides (TMDs). These materials exhibit high carrier mobility at the atomic-scale thickness, and have reduced interface defects due to their dangling-bond-free surfaces. These unique properties contribute significantly to miniaturization and performance improvement of electronic devices. The ultra-thin structure of 2D semiconductor materials can break through the scaling limit of conventional materials, and the high carrier mobility and low-power characteristics are beneficial to the improvement of operational speed and energy efficiency.

Notably, 2D semiconductor materials exhibit unique advantages in non-volatile memories. As a typical non-volatile memory technology, silicon-based flash memory is limited by the efficiency of charge tunneling, making it difficult to achieve both fast programming speed and non-volatility simultaneously. The 2D materials, due to the perfect lattice interface and inherent ultra-thin interface, have received widespread interest in the enhancement of the programming speed of semiconductor flash memory devices.

### SUMMARY

An object of the disclosure is to provide an ultrafast two-dimensional flash memory device with nanosecond-order program/erase speed based on Fowler-Nordheim (FN) tunneling and a preparation method thereof to overcome the limitations of low programming speed in the conventional flash memories and to offer a novel technical approach for the development of high-performance and low-energy consumption memories.

Technical solutions of the present disclosure are described as follows.

In a first aspect, this application provides an ultrafast two-dimensional (2D) flash memory device based on Fowler-Nordheim (FN) tunneling, comprising:
a substrate;
a gate electrode;
a blocking layer;
a floating gate;
a tunneling layer;
a two-dimensional (2D) channel;
a source electrode; and
a drain electrode;
wherein the gate electrode is provided at a middle of the substrate;
the blocking layer is configured to cover the gate electrode and the substrate;
the floating gate is provided on the blocking layer;
the tunneling layer is configured to cover the floating gate and the blocking layer; and
the 2D channel is provided on the tunneling layer.

In some embodiments, as shown in a top view of FIG. 2, the floating gate is entirely encompassed within a coverage area of the gate electrode;
the 2D channel is entirely encompassed within a coverage area of the floating gate; and
the source electrode and the drain electrode are configured to partially overlap with the 2D channel.

In some embodiments, the substrate is made of a rigid material or a flexible material;
the rigid material is selected from the group consisting of silicon wafer, sapphire and mica; and
the flexible material is polyimide.

In some embodiments, a material of the gate electrode is selected from the group consisting of platinum (Pt), gold (Au), chromium (Cr), antimony (Sb), bismuth (Bi), titanium (Ti) and palladium (Pd).

In some embodiments, the blocking layer and the tunneling layer are each independently made of a material selected from the group consisting of HfOₓ, AlOₓ, ZrOₓ and hBN, wherein x represents a ratio of the oxygen atom to the metal atom in the metal oxide; and
the blocking layer has a thickness of 10-50 nm.

In some embodiments, the floating gate is made of platinum (Pt), gold (Au) or graphene; and
the floating gate has a thickness of 0.5-3 nm.

In some embodiments, the 2D channel is made of a material selected from the group consisting of MoS₂, WSe₂, WS₂, BP, InSe and MoTe₂.

In some embodiments, the source electrode and the drain electrode are each independently made of a material selected from the group consisting of platinum (Pt), gold (Au), chromium (Cr), antimony (Sb), bismuth (Bi), titanium (Ti) and palladium (Pd).

In a second aspect, as shown in a flowchart of FIG. 4, the present disclosure provides a method for preparing the ultrafast 2D flash memory device, comprising:
(1) depositing a first photoresist layer on the substrate followed by patterning to define a gate electrode formation region, depositing a first metal material within the gate electrode formation region, and stripping the first photoresist layer to form the gate electrode on the substrate;
wherein the patterning technology comprises but is not limited to a photolithography technique selected from ultraviolet lithography, laser direct writing and electron-beam lithography; and
the deposition technology comprises but is not limited to a technique selected from electron-beam evaporation, thermal evaporation and physical vapor deposition;
(2) depositing a first dielectric material on the substrate by atomic layer deposition (ALD) to form the blocking layer;
in some embodiments, the blocking layer has a thickness of 10-50 nm;
(3) depositing a second photoresist layer on the blocking layer followed by patterning to define a floating gate formation region, depositing a second metal material within the floating gate formation region, and stripping the second photoresist layer to form the floating gate; or
transferring a patterned two-dimensional conductive material onto the blocking layer to form the floating gate;
wherein the two-dimensional conductive material is graphene;
in some embodiments, the floating gate has a thickness of 0.5-3 nm;
(4) depositing a second dielectric material on the blocking layer by the ALD to form the tunneling layer; or
transferring a third dielectric material with a 2D configuration onto the blocking layer to form the tunneling layer;
in some embodiments, the tunneling layer has a thickness of 5-20 nm;
(5) transferring a two-dimensional semiconductor material onto the tunneling layer to form the 2D channel; and
wherein the two-dimensional semiconductor material has a monolayer or multi-layer structure obtained by mechanical exfoliation or chemical vapor deposition; and
(6) preparing the source electrode and the drain electrode.

In some embodiments, the method provided herein further comprises:
optimizing thickness ratio and dielectric constants of the blocking layer, the floating gate and the tunneling layer to achieve optimal capacitance matching and auxiliary barrier formation;
in some embodiments, a thinner tunneling layer facilitates enhanced tunneling efficiency but degrades retention characteristics, while a thicker blocking layer results in improved retention at the expense of tunneling performance;

performing source-drain contact design to arrive at a desired transport polarity for the flash memory device, wherein when the 2D channel is made of WSe₂ having a valence band maximum of 5.2 eV and a conduction band minimum of 3.5 eV, a low work-function metal selected from the group consisting of Bi and Sb is selected to achieve N-type contact, a high work-function metal selected from the group consisting of Pt and Pd is selected to achieve P-type contact, or Cr with a mid-work function is selected to achieve an ambipolar contact;
wherein step (5) further comprises:
   performing mixed-gas annealing or thermal annealing to remove organic residues;
step (1) further comprises:
   cleaning a surface of the gate electrode with oxygen plasma followed by inspection under an atomic force microscope or a scanning electron microscope; and
step (3) further comprises:
   cleaning a surface of the floating gate with oxygen plasma followed by inspection under the atomic force microscope or the scanning electron microscope.

Compared to the prior art, the present disclosure has the following beneficial effects.

The ultrafast 2D flash memory device provided herein utilizes the auxiliary barrier formed by the ultrathin interface of two-dimensional materials to enable ultrafast charge storage. FIGS. 3A-3B illustrates an energy band diagram and the corresponding ultrafast programming mechanism of the device provided herein. In FIGS. 3A-3B, region 1 denotes the drain electrode, region 2 represents a two-dimensional semiconductor channel, region 3 corresponds to the tunneling layer, and region 4 denotes the floating gate. When a forward programming voltage is applied to the gate electrode (as shown in FIG. 3A), a dual-triangular tunneling barrier is formed. Upon further increasing the programming voltage, a slope of the energy band slope continues to increase (as shown in FIG. 3B), enabling high-energy ballistic electrons to tunnel through a narrow triangular barrier and be directly captured by the floating gate without encountering additional energy barriers. This process facilitates a significant tunneling current, thereby substantially reducing the programming time and achieving high-speed operation.

The ultrafast 2D flash memory device provided herein leverages band structure engineering and interface engineering of two-dimensional materials to significantly enhance programming efficiency, thereby achieving nanosecond-order program/erase speed while maintaining nonvolatile retention for over 10 years and enduring over one million program/erase cycles. The present disclosure effectively overcomes the speed limitations of conventional flash memories and provides an innovative solution for the development of high-performance nonvolatile memory technologies.

### BRIEF DESCRIPTION OF THE DRAWINGS

FIG. 1 is a side elevation view of an ultrafast 2D flash memory device based on Fowler-Nordheim (FN) tunneling according to an embodiment of the present disclosure;

FIG. 2 is a top view of the ultrafast 2D flash memory device according to an embodiment of the present disclosure;

FIGS. 3A-3B schematically show an ultrafast operation mechanism of the ultrafast 2D flash memory device according to an embodiment of the present disclosure; and

FIG. 4 is a flowchart of a method for preparing the ultrafast 2D flash memory device according to an embodiment of the present disclosure.

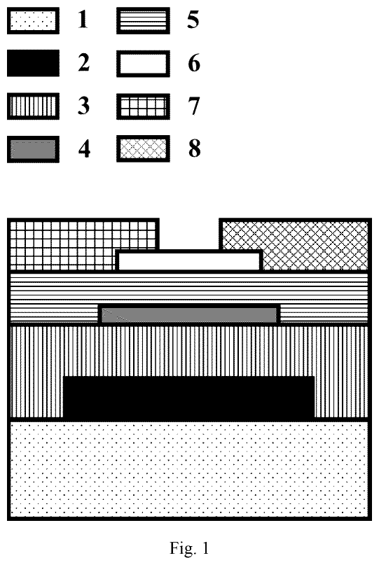

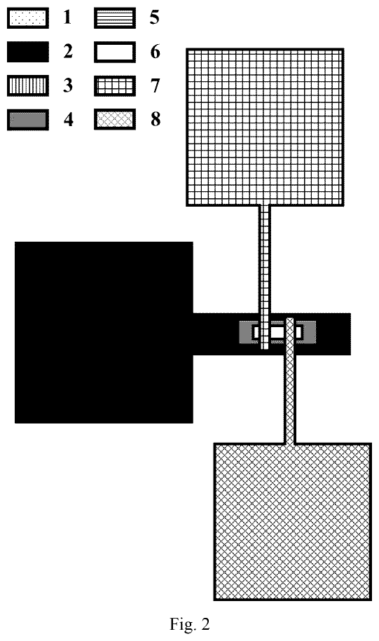

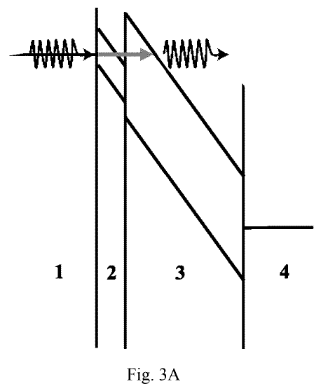

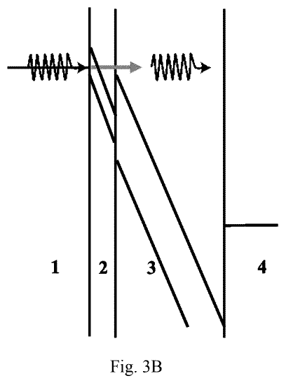

### DETAILED DESCRIPTION OF EMBODIMENTS

The technical solutions of the present disclosure will be described in further detail below with reference to the accompanying drawings and embodiments.

As used herein, the orientation or positional relationships indicated by terms, such as “up”, “down”, “vertical” and “horizontal”, are based on those shown in the accompanying drawings. These terms are solely for the convenience of describing the present disclosure in a simplified manner, and are not intended to indicate or imply that the devices or components must have specific orientations or be constructed and operated in such orientations. Therefore, these terms should not be understood as limitations of the present disclosure.

Moreover, it should be understood that various details, such as the device structure, materials, dimensions, and fabrication processes, are provided to enable those skilled in the art to better understand the present disclosure. However, the implementation of the present disclosure is not limited to these specific details. Unless otherwise specified, various components of the device may be made using materials conventionally known in the art, or alternatively, functionally-similar materials that may be developed in the future.

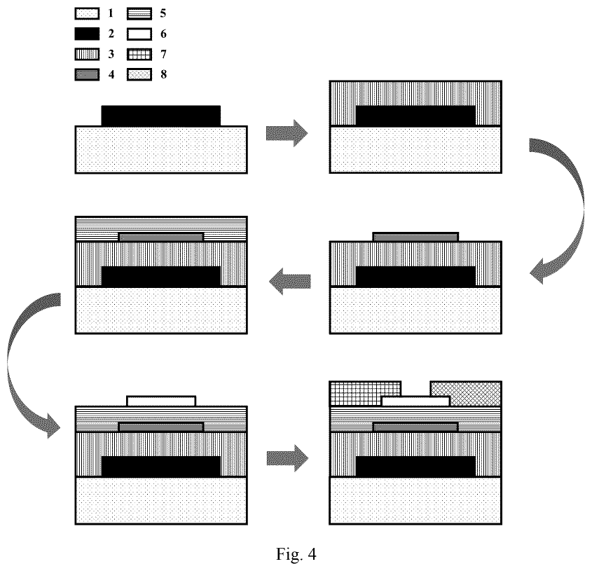

As shown in FIG. 4, an embodiment of the present disclosure provides a method for preparing an ultrafast two-dimensional (2D) flash memory device based on Fowler-Nordheim (FN) tunneling, which is performed as follows.

(1) A first photoresist layer was deposited on a p-type heavily-doped silicon substrate covered by a 300-nm-thick SiO₂ layer, patterned by electron-beam lithography and developed to form a first positive photoresist pattern. A Ti/Au metal film (3 nm/15 nm) was deposited on the first positive photoresist pattern through electron-beam evaporation. Then, the first photoresist layer was stripped using an acetone solution to form a gate electrode.

(2) A first oxygen plasma treatment was performed on the gate electrode and the aforementioned substrate at 50 W for 20 s, after which a 20-nm-thick high-κ HfO₂ dielectric film was deposited by atomic layer deposition (ALD) at 250° C. to form a blocking layer.

(3) A second photoresist layer was deposited on the blocking layer by electron-beam lithography, and developed to form a second positive photoresist pattern. A 1 nm-thick Pt layer was deposited on the second positive photoresist pattern through electron-beam evaporation. Then, the second photoresist layer was stripped using the acetone solution to form a floating gate.

(4) A second oxygen plasma treatment (50 W, 20 s) was performed on the floating gate and the blocking layer, after which an 8-nm-thick high-κ HfO₂ dielectric film was deposited at 250° C. by the ALD to form a tunneling layer.

(5) A monolayer MoS₂ film was mechanically exfoliated from bulk MoS₂ material and transferred onto the tunneling layer using a dry transfer process with polydimethylsiloxane (PDMS), followed by annealing at 200° C. for 2 h under a nitrogen atmosphere. The monolayer MoS₂ film was patterned by electron-beam lithography, and developed to form a negative photoresist pattern. Excess MoS₂ film was removed by reactive ion etching at 30 W for 20 s under an oxygen atmosphere. The remaining photoresist was stripped using N-Methyl-2-pyrrolidone (NMP) to form a 2D channel.

(6) A third photoresist layer and a fourth photoresist layer were deposited on the 2D channel and the tunneling layer and developed to form a third positive photoresist pattern and a fourth positive photoresist pattern. A Cr/Au bilayer (5 nm/30 nm) was respectively deposited on the third positive photoresist pattern and the fourth positive photoresist pattern through electron-beam evaporation. Then, the third photoresist layer and the fourth photoresist layer were stripped using the acetone solution to form the source electrode and the drain electrode.

The ultrafast FN tunneling flash memory device provided herein is operated for programming and erasing as follows.

For the programming operation, the source electrode and the drain electrode are grounded, and a nanosecond-scale positive voltage pulse is applied to the gate electrode. Electrons in the 2D material channel are injected into the floating gate through the tunneling layer via FN tunneling. The accumulation of electrons in the floating gate causes a positive shift in the threshold voltage of the device, thereby enabling nanosecond-scale programming. For the erasing operation, the source electrode and the drain electrode are grounded, and a nanosecond-order negative voltage pulse is applied to the gate electrode. Electrons stored in the floating gate tunnel back to the 2D material channel through the tunneling layer. The loss of electrons in the floating gate results in a negative shift in the threshold voltage, thereby enabling nanosecond-order erasing. Performance tests demonstrate that the device provided herein is capable of retaining its nonvolatile characteristics for 10 years under nanosecond-order program/erase operations and exhibits an endurance exceeding one million program/erase cycles.

Described embodiments are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A two-dimensional (2D) flash memory device with nanosecond-order program/erase speed based on Fowler-Nordheim (FN) tunneling, comprising:
a substrate;
a gate electrode;
a blocking layer;
a floating gate;
a tunneling layer;
a two-dimensional (2D) channel;
a source electrode; and
a drain electrode;
wherein the gate electrode is provided at a middle of the substrate;
the blocking layer is configured to cover the gate electrode and the substrate;
the floating gate is provided on the blocking layer;
the tunneling layer is configured to cover the floating gate and the blocking layer;
the 2D channel is provided on the tunneling layer;
the floating gate is entirely encompassed within a coverage area of the gate electrode;
the 2D channel is entirely encompassed within a coverage area of the floating gate; and
the source electrode and the drain electrode are configured to partially overlap with the 2D channel.

2. The 2D flash memory device of claim 1, wherein the substrate is made of a rigid material or a flexible material;
the rigid material is selected from the group consisting of silicon wafer, sapphire and mica; and
the flexible material is polyimide.

3. The 2D flash memory device of claim 1, wherein a material of the gate electrode is selected from the group consisting of platinum (Pt), gold (Au), chromium (Cr), antimony (Sb), bismuth (Bi), titanium (Ti) and palladium (Pd).

4. The 2D flash memory device of claim 1, wherein the blocking layer and the tunneling layer are each independently made of a material selected from the group consisting of HfOₓ, AlOₓ, ZrOₓ and hBN; and
the blocking layer has a thickness of 10-50 nm.

5. The 2D flash memory device of claim 1, wherein the floating gate is made of platinum (Pt), gold (Au) or graphene; and
the floating gate has a thickness of 0.5-3 nm.

6. The 2D flash memory device of claim 1, wherein the 2D channel is made of a material selected from the group consisting of MoS₂, WSe₂, WS₂, BP, InSe and MoTe₂.

7. The 2D flash memory device of claim 1, wherein the source electrode and the drain electrode are each independently made of a material selected from the group consisting of platinum (Pt), gold (Au), chromium (Cr), antimony (Sb), bismuth (Bi), titanium (Ti) and palladium (Pd).

8. A method for preparing the 2D flash memory device of claim 1, comprising:
(1) depositing a first photoresist layer on the substrate followed by patterning to define a gate electrode formation region, depositing a first metal material within the gate electrode formation region, and stripping the first photoresist layer to form the gate electrode on the substrate;
(2) depositing a first dielectric material on the substrate by atomic layer deposition (ALD) to form the blocking layer;
(3) depositing a second photoresist layer on the blocking layer followed by patterning to define a floating gate formation region; depositing a second metal material within the floating gate formation region, and stripping the second photoresist layer to form the floating gate; or
transferring a patterned two-dimensional conductive material onto the blocking layer to form the floating gate;
(4) depositing a second dielectric material on the blocking layer by the ALD to form the tunneling layer; or
transferring a third dielectric material with a 2D configuration onto the blocking layer to form the tunneling layer;
(5) transferring a two-dimensional semiconductor material onto the tunneling layer to form the 2D channel; and
wherein the two-dimensional semiconductor material has a monolayer or multi-layer structure obtained by mechanical exfoliation or chemical vapor deposition; and
(6) preparing the source electrode and the drain electrode.

9. The method of claim 8, further comprising:
optimizing thickness ratio and dielectric constants of the blocking layer, the floating gate and the tunneling layer to achieve optimal capacitance matching and auxiliary barrier formation; and
performing source-drain contact design to arrive at a desired transport polarity for the flash memory device, wherein when the 2D channel is made of WSe₂ having a valence band maximum of 5.2 eV and a conduction band minimum of 3.5 eV, a low work-function metal selected from the group consisting of Bi and Sb is selected to achieve N-type contact, a high work-function metal selected from the group consisting of Pt and Pd is selected to achieve P-type contact, or Cr with a mid-work function is selected to achieve an ambipolar contact;
wherein step (5) further comprises:
performing mixed-gas annealing or thermal annealing to remove organic residues;
step (1) further comprises:
cleaning a surface of the gate electrode with oxygen plasma followed by inspection under an atomic force microscope or a scanning electron microscope; and
step (3) further comprises:
cleaning a surface of the floating gate with oxygen plasma followed by inspection under the atomic force microscope or the scanning electron microscope.
